(19) United States
(12) Patent Application Publication
(10) Pub. No.: US 2012/0012842 A1
(43) Pub. Date: Jan. 19, 2012

(54) SEMICONDUCTOR DEVICE HAVING FUNCTION OF TRANSMITTING/RECEIVING

(75) Inventor: Yu Kikuchi, Kanagawa-ken (JP)

(73) Assignee: Kabushiki Kaisha Toshiba, Tokyo (JP)

(21) Appl. No.: 13/044,380

(22) Filed: Mar. 9, 2011

(30) Foreign Application Priority Data
Jul. 16, 2010 (JP) P2010-161156

(51) Int. Cl. H01L 23/544

(52) U.S. Cl. 257/48; 257/E23.179

(57) ABSTRACT

In one embodiment, a semiconductor device includes an integrated circuit formed in an area enclosed by dicing lines formed in a matrix manner, and a signal wiring formed on at least one of the dicing lines. The integrated circuit includes a transmitter circuit having a signal output pad, a receiver circuit having a signal input pad and an internal circuit to process data inputted to the transmitter circuit and outputted from the receiver circuit. The signal wiring electrically connects the signal output pad and the signal input pad.

### CROSS REFERENCE TO RELATED APPLICATION

This application is based upon and claims the benefit of priority from the prior Japanese Patent Application No. 2010-161156, filed on Jul. 16, 2010, the entire contents of which are incorporated herein by reference.

### FIELD

Embodiments described herein relate generally to a semiconductor device.

### BACKGROUND

As semiconductor devices become smaller and achieve a higher packaging density and more functions, many process and device characteristics are measured with a test circuit during a manufacturing process of the semiconductor devices, and the manufacturing process is managed based on the measured result.

In most cases, the test circuit is not necessary after the semiconductor device is completed. Therefore, the test circuit is formed on a dicing line along which a semiconductor substrate is divided into chips in order to increase the number of semiconductor devices manufactured from one semiconductor substrate and reduce the manufacturing cost.

In a case where a semiconductor device is an integrated circuit including a transmitter circuit and a receiver circuit, it is necessary to check whether a transmission path around an input terminal of the receiver circuit and an output terminal of the transmitter circuit is operating normally or not. The check is called an external loopback test. In the check, a signal transmitted from the transmitter circuit is received by the receiver circuit via a wiring arranged outside of the integrated circuit. More specifically, the receiving side compares expected values to check whether data are correctly transmitted and received.

The external loopback test is performed as follows, for example. First, probes are respectively brought into contact with the input terminal of the receiver circuit and the output terminal of the transmitter circuit, and leading lines of the probes are connected outside so as to form a signal transmission path. Subsequently, the transmitter circuit transmits data, and the receiver circuit receives the data via the signal transmission path. Then, the transmission data and the reception data are collated with each other, based on which a determination is made as to whether the transmission path is normal or not.

However, the leading lines of the probes are thicker and longer wirings than signal wirings used when an integrated circuit is mounted. Accordingly, the signal transmission path has a large capacitance outside. As a result, when the transmission speed increases, the transmitter circuit and the receiver circuit fail to operate normally. Therefore, there is a problem in that the external loopback test cannot be performed.

### BRIEF DESCRIPTION OF THE DRAWINGS

FIG. 1 is a top view showing a semiconductor device according to a first embodiment;

FIG. 2 is a top view showing the main portion of the semiconductor device according to the first embodiment;

FIG. 3 is a diagram showing a signal transmission method according to the first embodiment;

FIG. 4 is a top view showing the pattern of the signal wiring according to the first embodiment;

FIG. 5 is a magnified top view showing the main portion of the semiconductor device according to the first embodiment;

FIG. 6 is a top view showing another route of the signal wiring according to the first embodiment;

FIG. 7 is a top view showing another signal wiring according to the first embodiment;

FIG. 8 is a top view showing the pattern of the signal wiring according to a second embodiment;

FIG. 9 is a top view showing another pattern of the signal wiring according to the second embodiment;

FIG. 10 is a top view showing farther another pattern of the signal wiring according to the second embodiment;

FIG. 11 is a top view showing the main portion of the semiconductor device according to a third embodiment;

FIG. 12 is a top view showing the main portion of the semiconductor device according to a fourth embodiment;

FIG. 13 is a top view showing the main portion of another semiconductor device according to the fourth embodiment;

FIG. 14 is a top view showing the main portion of father another semiconductor device according to the fourth embodiment;

FIG. 15 is a top view showing the main portion of the semiconductor device according to a fifth embodiment;

FIG. 16 is a top view showing the main portion of another semiconductor device according to the fifth embodiment;

FIG. 17 is a top view showing the main portion of another semiconductor device according to the fifth embodiment;

FIG. 18 is a top view showing the main portion of father another semiconductor device according to the fifth embodiment;

FIG. 19 is a top view showing the main portion of the semiconductor device according to a sixth embodiment.

### DETAILED DESCRIPTION

In one embodiment, a semiconductor device includes an integrated circuit formed in an area enclosed by a plurality of dicing lines formed in a matrix manner, and a signal wiring formed on at least one of the dicing lines. The integrated circuit includes a transmitter circuit having a signal output pad, a receiver circuit having a signal input pad and an internal circuit to process data inputted to the transmitter circuit and outputted from the receiver circuit. The signal wiring electrically connects the signal output pad and the signal input pad.

Hereinafter, further embodiments will be described with reference to the drawings. In the drawings, same reference characters denote the same or similar portions.

### First Embodiment

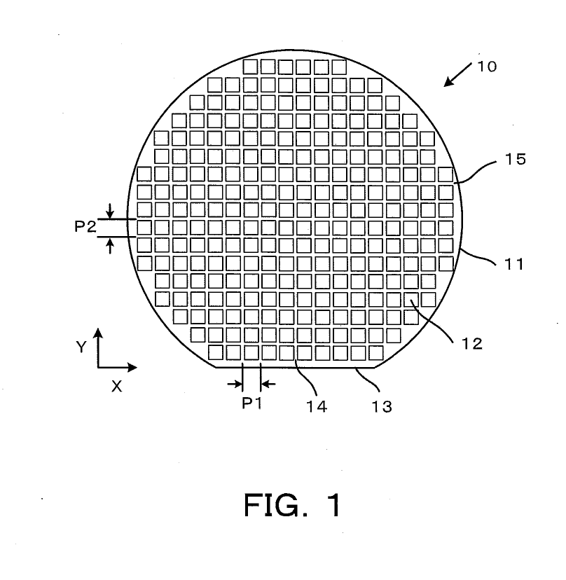

A first embodiment will be described with reference to FIGS. 1 to 7. FIG. 1 is a top view showing a semiconductor device of the embodiment. As shown in FIG. 1, the semiconductor device of the embodiment has a semiconductor substrate 11 made of a silicon substrate having a diameter of 200 mm, for example. The main plane (surface) of the semiconductor substrate 11 is formed with a plurality of integrated circuit 12, e.g., integrated circuits in the order of several millimeters, for example.

The integrated circuits 12 are arranged with a pitch P1 in an X direction, which is in parallel with an orientation flat 13, and with a pitch P2 in a Y direction perpendicular to the X direction. A space between the adjacent integrated circuits 12 in the X direction is a dicing line 14 arranged with the pitch P1 in the X direction. Likewise, a space between the adjacent integrated circuits 12 in the Y direction is a dicing line 15 arranged with the pitch P2 in the Y direction.

In other words, the dicing lines 14, 15 are formed in a matrix manner on the main surface of the semiconductor substrate 11. The integrated circuits 12 are formed in an area enclosed by the dicing lines 14, 15 formed in a matrix manner.

The semiconductor device 10 is divided into semiconductor chips as follows. The semiconductor substrate 11 is placed on a dicing tape, and the semiconductor substrate 11 is cut along the dicing line 14 and the dicing line 15 by a blade having a thickness of 50 μm, for example. Thus, the semiconductor substrate 11 is divided into semiconductor chips having the integrated circuits 12 thereon. A width W of the dicing line 14 and the dicing line 15 is about 100 μm, which is twice the thickness of the blade, for example.

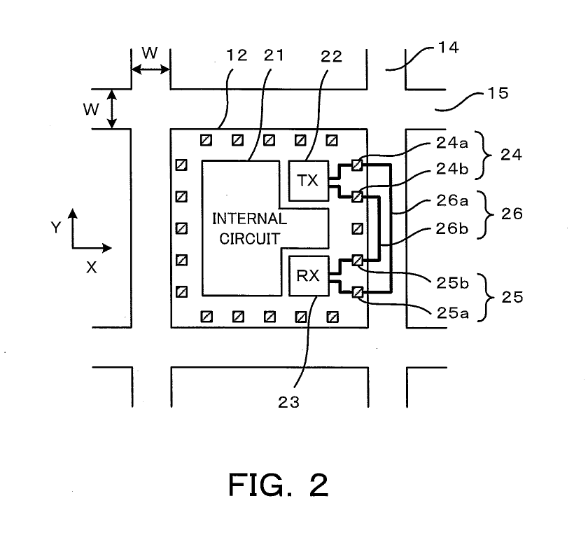

FIG. 2 is a top view showing a main portion of the semiconductor device 10. As shown in FIG. 2, the integrated circuit 12 is an integrated circuit having a function of transmitting/receiving, e.g., serial data to/from the outside at a high speed. The integrated circuit 12 includes an internal circuit 21, a transmitter circuit 22, and a receiver circuit 23.

The internal circuit 21 processes data inputted to the transmitter circuit 22 and outputted from the receiver circuit 23. The transmitter circuit 22 generates a transmission signal based on data processed by the internal circuit 21, and transmits the transmission signal to the outside via a signal output pad 24. The receiver circuit 23 receives the signal from the outside via a signal input pad 25, generates data based on the received signal, and gives the data to the internal circuit 21.

The transmitter circuit 22 and the receiver circuit 23 are formed along one side in parallel with the Y direction of the integrated circuit 12. On the dicing line 14, a signal wiring 26 is formed to electrically connect the signal output pad 24 and the signal input pad 25 along one side in parallel with the Y direction.

In the embodiment, a signal transmission method is LVDS (Low Voltage Differential signaling). It is well known that the LVDS is a digital wired transmission technique for short distance communication, and is a differential interface operating at a relatively high speed with small amplitude and low power consumption.

Therefore, the signal output pad 24 includes a pair of pads 24a, 24b for outputting a differential signal. The signal input pad 25 includes a pair of pads 25a, 25b for receiving the differential signal. The signal wiring 26 includes a pair of wirings 26a, 26b for transmitting the different signal. The pad 24a and the pad 25a are connected via an outer wiring 26a (second wiring) far side from the integrated circuit 12. The pad 24b and the pad 25b are connected via an inner wiring 26b (first wiring) closer to the integrated circuit 12.

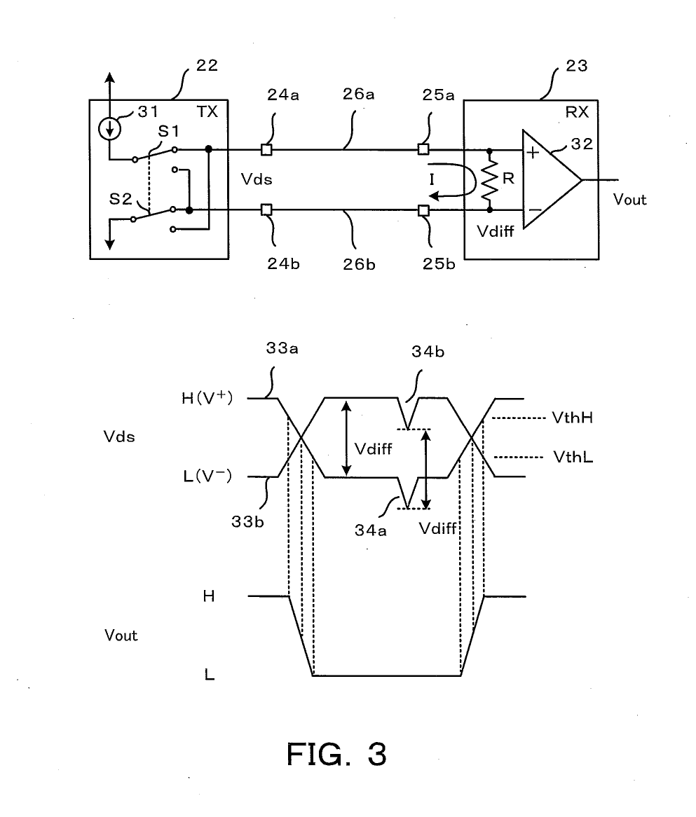

FIG. 3 is a diagram showing a signal transmission method. As shown in FIG. 3, the transmitter circuit 22 includes a constant current source 31 and double-throw switches S1, S2 for switching a current path. The transmitter circuit 22 generates a differential signal Vds by synchronously switching the switches S1, S2 based on data provided from the internal circuit 21 while the constant current source 31 causes a current I to flow through a resistor R.

The differential signal Vds is constituted by a data signal 33a and a clock signal 33b complementary therewith. The transmitter circuit 22 outputs the data signal 33a via the pad 24a, and outputs the clock signal 33b via the pad 24b. Data is transferred by mutually referring to the data signal 33a and the clock signal 33b.

The receiver circuit 23 includes a comparator 32 and a resistor R connected between two input terminals of the comparator 32. The receiver circuit 23 makes an output Vout at High level when a differential voltage Vdiff between the data signal 33a and the clock signal 33b is larger than a threshold value VthH. The receiver circuit 23 makes the output Vout at Low level when the differential voltage Vdiff is smaller than a threshold value VthL.

It is well known that the LVDS uses the differential signal to transfer data. Therefore, there is an advantage in that the LVDS is more likely to remove common mode noises 34a, 34b than a single end method.

Subsequently, a pattern of the signal wiring 26 will be described. The signal wiring 26 needs to have the same signal propagation delay for the pair of wirings 26a, 26b in order to transmit the differential signal. In a case where the wiring 26a and the wiring 26b have different signal propagation delays, a phase difference occurs between the data signal 33a and the clock signal 33b, which makes it difficult to transmit the signal at a high speed.

The signal propagation delays of the wiring 26a and the wiring 26b depend on transmission path lengths and load capacitances of the wiring 26a and the wiring 26b. Therefore, the wiring 26a and the wiring 26b need to have the same transmission path length and the same load capacitance.

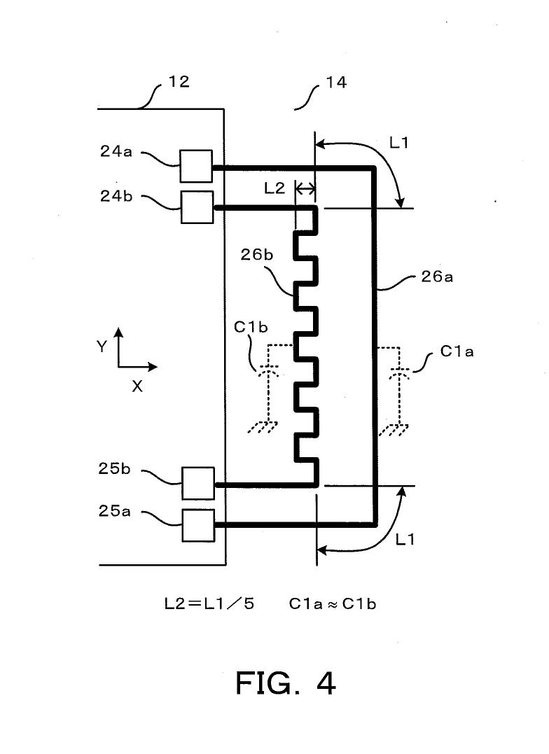

FIG. 4 is a top view showing the pattern of the signal wiring 26. As shown in FIG. 4, the pattern of the signal wiring 26 is configured such that the outer wiring 26a and the inner wiring 26b basically have the same transmission path length.

The pattern of the wiring 26a includes leading portions extending from the pads 24a, 25a in parallel with the X direction and a central portion continuing from the leading portions in parallel with the Y direction. Likewise, the pattern of the wiring 26b includes leading portions extending from the pads 24b, 25b in parallel with the X direction and a central portion continuing from the leading portions in parallel with the Y direction.

However, the shape of the central portion of the wiring 26a is different from the shape of the central portion of the wiring 26b. The central portion of the wiring 26a is straight. On the other hand, the central portion of the wiring 26b is in a rectangular waveform. The number of rectangular waves of the wiring 26b and a height L2 of the rectangular wave are configured such that the transmission path length of the wiring 26a is the same as the transmission path length of the wiring 26b.

Where the central portion of the wiring 26b is straight, a difference (inner periphery difference) between the transmission path length of the wiring 26a and the transmission path length of the wiring 26b is defined as 2L1. When the number of rectangular waves is 5, the height L2 of the rectangular wave is L1/5, for example. The duty of the rectangular wave may be any value. In this embodiment, the duty is set at 50%.

As a result, the wiring 26 and the wiring 26b have substantially the same transmission path length and the same load capacitances C1a, C1b respectively. Therefore, the wiring 26 and the wiring 26b can have the same signal propagation delay.

In a manufacturing step of the semiconductor device 10, the signal wiring 26, the signal output pad 24 and the signal input pad 25 can be formed at a time. More specifically, an aluminum film for pads may be formed on the semiconductor substrate 11, and a lithography method may be used to form the signal output pad 24, the signal input pad 25, and the signal wiring 26 by means of the patterning process performed at a time. Therefore, this does not affect the number of manufacturing steps and the manufacturing cost.

Using the above, the external loopback test is performed in the following order, for example. The internal circuit 21 prepares data to be transmitted. The transmitter circuit 22 transmits data to the receiver circuit 23 via the signal wiring 26. The receiver circuit 23 receives the transmitted data. The internal circuit 21 collates the transmitted data with the received data. A determination is made as to whether the transmission path around the signal transmission pad 24 and the signal reception pad 25 is normal or not.

When the external loopback test is finished, the signal wiring 26 is not necessary. When the semiconductor substrate 11 is divided into semiconductor chips along the dicing lines 14, 15, the signal wiring 26 on the dicing line 14 is removed by dicing. Therefore, the signal wiring 26 does not affect the obtained semiconductor chips at all.

As described above, a width W of the dicing line 14 and the dicing line 15 is about 100 μm, which is twice the thickness of the blade. Therefore, the signal wiring 26 is preferably arranged such that at least the leading portions extending from the pads 24a, 24b, 25a, 25b in parallel with the X direction are formed to extend beyond the center line of the dicing line 14, so that the signal wiring 26 is cut off by the dicing. This is because, if the offset between the blade and the dicing line 14 is too large, the wirings 26a, 26b remain without being cut off, which affects the operation of the integrated circuit 12.

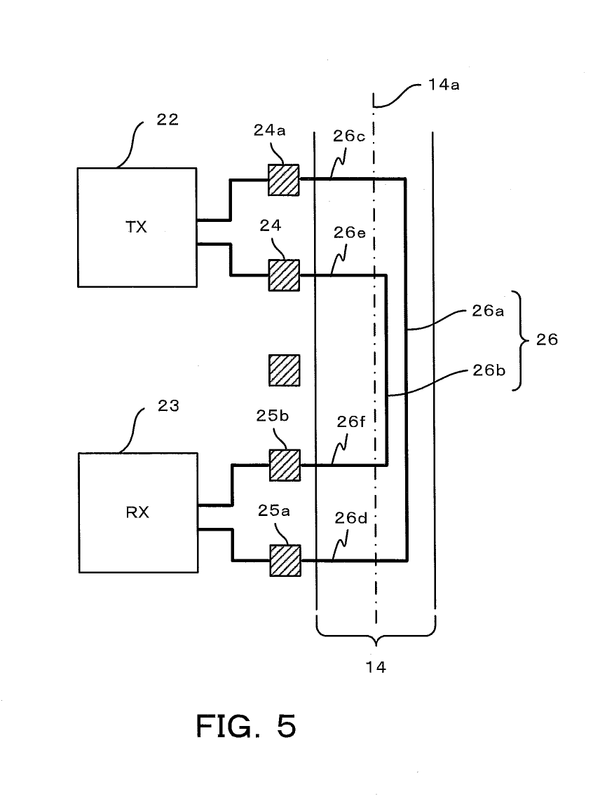

FIG. 5 is a top view showing the leading portions intersecting the dicing line at a right angle and extending beyond the center line. As shown in FIG. 5, the leading portions 26c, 26d of the wiring 26a intersect the dicing line 14 at a right angle and extend beyond the center line 14a of the dicing line 14. Likewise, the leading portions 26e, 26f of the wiring 26b intersect the dicing line 14 at a right angle and extend beyond the center line 14a of the dicing line 14.

The signal wiring 26 is preferably made of aluminum or an alloy mainly including aluminum such as an alloy including aluminum and silicon. When the signal wiring 26 is cut by the dicing, cut-surfaces of the leading portions extending from the pads 24a, 24b, 25a, 25b in parallel with the X direction are exposed. When the cut-surfaces are exposed to fresh air, the cut-surfaces are oxidized. When the aluminum is oxidized, an alumina film is formed on the surface. The alumina film prevents corrosion of the aluminum inside.

As described above, the semiconductor device 10 of the embodiment has the signal wiring 26 formed on the dicing line 14 to electrically connect the signal output pad 24 of the transmitter circuit 22 and the signal input pad 25 of the receiver circuit 23.

As a result, this configuration greatly reduces the transmission path length of the signal wiring 26 and greatly reduces the load capacitances C1a, C1b, compared with the signal wiring obtained by externally connecting the leading lines of the respective probes in contact with the signal output pad 24 and the signal input pad 25.

Accordingly, the external loopback test can be performed at a high signal transmission speed. Therefore, a semiconductor device with which the external loopback test can be easily performed is obtained.

In this description, the central portion of the wiring 26b is in the rectangular waveform. However, any other form can be employed as long as the transmission path length of the wiring 26a is the same as the transmission path length of the wiring 26b. Examples of forms include a trapezoid shape, a triangular shape, a sine wave shape, and any other shape made of a combination of straight lines and curved lines.

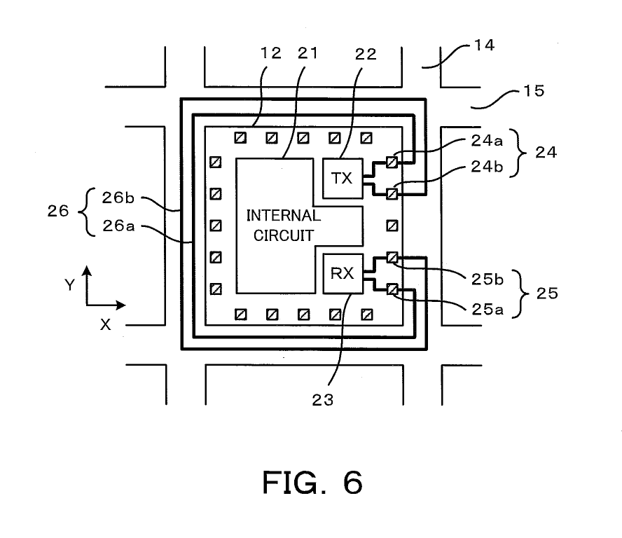

In this description, the signal output pad 24 and the signal input pad 25 are connected through the route as short as possible. Alternatively, they may be connected through other routes. FIG. 6 is a figure showing another route of the signal wiring.

As shown in FIG. 6, the signal wiring 26 is formed around the integrated circuit 12 on the dicing line 14 and the dicing line 15. In this case, the signal output pad 24 and the signal input pad 25 are connected through the route as long as possible.

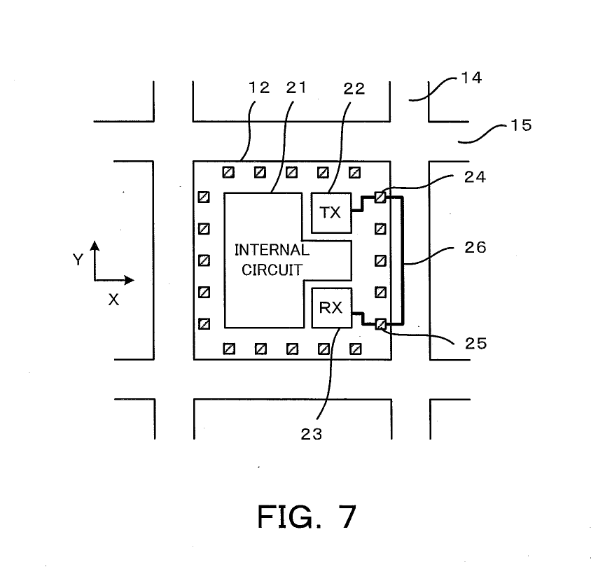

In this description, the transmission method is VLDS. However, the transmission method is not particularly limited thereto. The transmission method may be an ordinary single end method, for example. In this case, as shown in FIG. 7, the signal wiring 26 has a single wiring.

### Second Embodiment

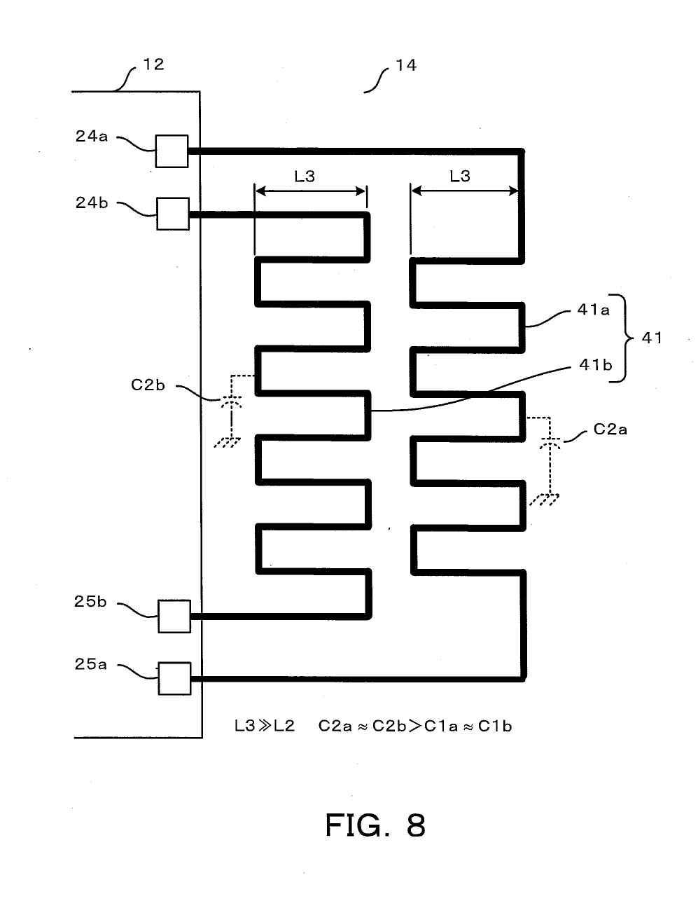

A semiconductor device of a second embodiment will be described with reference to FIGS. 8 to 10. FIG. 8 is a top view showing a pattern of a signal wiring of the embodiment. In the embodiment, the same constituent portions as those of the first embodiment are denoted with the same reference numerals, and the description thereabout will not be repeated. Only different portions will be described. The embodiment is different from the first embodiment in that the load capacitance of the signal wiring is increased.

As shown in FIG. 8, the signal wiring 41 of the embodiment includes a pair of wirings 41a, 41b. Central portions of the outer wiring 41a and the inner wiring 41b have rectangular waveforms respectively.

Both of the wirings 41a, 41b have the same number of rectangular waves and the same height L3 of the rectangular wave. The height L3 of the rectangular wave is sufficiently larger than the height L2 of the rectangular wave as shown in FIG. 4 (L3>×L2). Both of the wirings 41a, 41b have the same duty of the rectangular wave, e.g., 50%.

As a result, a load capacitance C2a of the wiring 41a is substantially the same as a load capacitance C2b of the wiring 41b, and the load capacitance C2a and the load capacitance C2b are larger than the load capacitances C1a and C1b as shown in FIG. 4 (C2a≈C2b>C1a≈C1b).

Like the first embodiment, it is to be understood that the transmission path length of the wiring 41a needs to be set at the same length as the transmission path length of the wiring 41b, although this is not described here.

Accordingly, this prevents excessive reduction of the load capacitances C2a, C2b, which may occur as the integrated circuit 12 becomes smaller, for example.

When the load capacitances C2a, C2b become closer to the load capacitances of the signal wirings respectively connected to the signal output pad 24 and the signal input pad 25 where the integrated circuit 12 is mounted, the external loopback test can be performed under a condition similar to the condition where the integrated circuit 12 is mounted.

As described above, the patterns of the central portions of both of the wirings 41a, 41b of the signal wiring 41 of the embodiment have rectangular shapes. As a result, the wirings 41a, 41b have larger load capacitances C2a, C2b.

This pattern is suitable for preventing excessive reduction of the load capacitances C2a, C2b, which may occur as the integrated circuit 12 becomes smaller, and performing the external loopback test under a condition where the integrated circuit 12 is mounted.

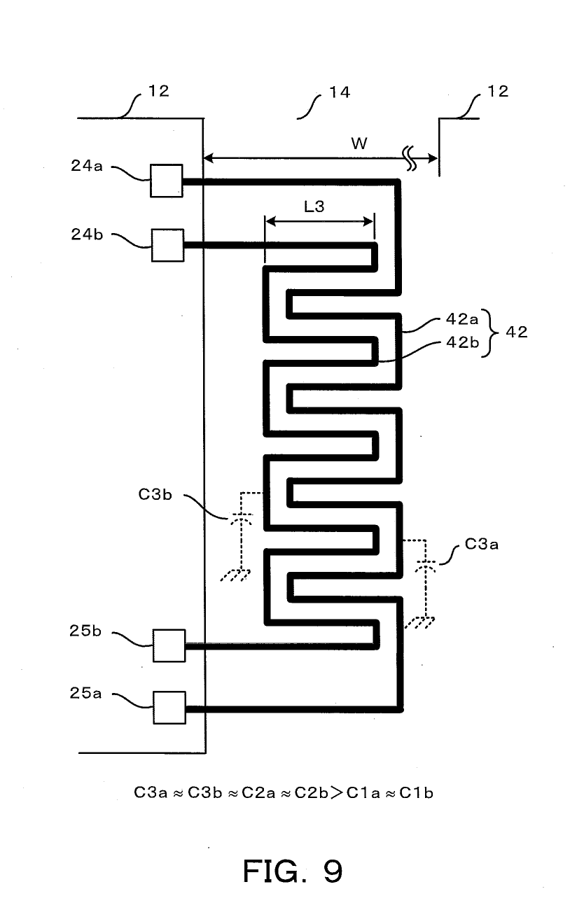

In the above description, the wirings 41a, 41b have the same duty of the rectangular wave. However, they may have different duties. FIG. 9 is a top view showing another pattern of the signal wiring. As shown in FIG. 9, the pattern of the signal wiring 42 is the same as the pattern of the signal wiring 41 as shown in FIG. 8, but wirings 42a, 42b have different duties of rectangular waves.

The duty of the rectangular wave of the wiring 42a is less than 50%, and the duty of the rectangular wave of the wiring 42b is more than 50%. A summation of them both is 100%. In other words, the patterns of the wiring 42a and the wiring 42b are left-right symmetrical with each other.

In this pattern, the signal wiring 42a and the signal wiring 42b can be arranged in proximity to each other in such a manner as to engage each other. This pattern is suitable for a case where load capacitances C3a, C3b are increased as much as possible even though the width W of the dicing line 14 is small.

The load capacitance C3a of the wiring 42a is substantially the same as the load capacitance C3b of the wiring 42b. Further, the number of rectangular waves of the wiring 42a and the number of rectangular waves of the wiring 42b are the same as the number of rectangular waves of the wiring 41a and the number of rectangular waves of the wiring 41b as shown in FIG. 8. Therefore, the wirings 42a, 42b have substantially the same load capacitances C3a, C3b as the load capacitances C2a, C2b (C3a≈C3b≈C2a≈C2b).

In the above description, the central portions of the wirings 41a, 41b have the rectangular waveforms. However, the central portions are not limited thereto. As long as the load capacitances can be increased in effect, any pattern can be employed.

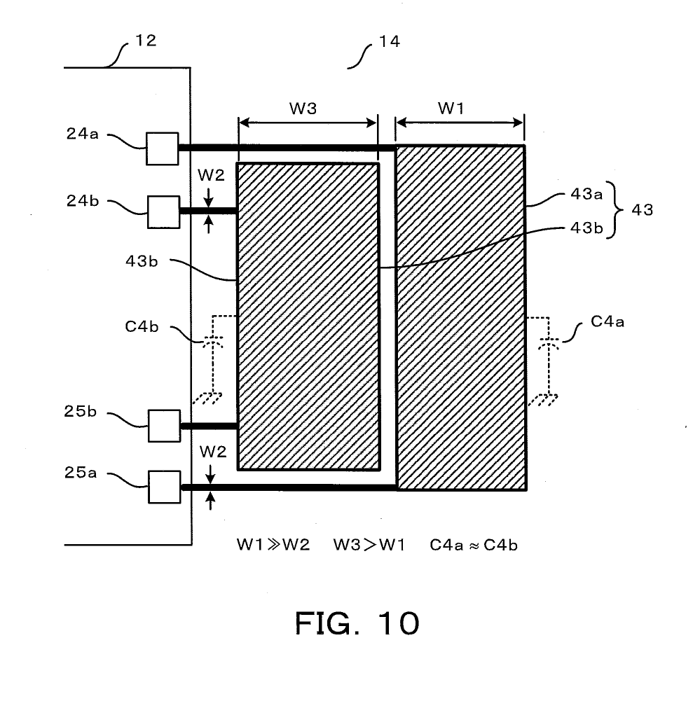

FIG. 10 is a top view showing still another pattern of the signal wiring. As shown in FIG. 10, the pattern of a signal wiring 43 is configured such that the central portions are in a planar shape. A width W1 of the central portion of a wiring 43a is greatly wider than a width W2 of a leading portion (W1>>W2).

A wiring 43b is configured in the same manner as the wiring 43a. A width W3 of the central portion of the wiring 43b is slightly larger than the width W1 of the central portion of the wiring 43a. This is because the size of the area of the central portion of the wiring 43b is preferably the same as the size of the area of the central portion of the wiring 43a. In this configuration, a load capacitance C4a of the wiring 43a becomes the same as a load capacitance C4b of the wiring 43b.

In the signal wiring 43, the central portions of the wirings 41a, 41b are in the planar shape. Therefore, the load capacitances can be greatly increased by the rectangular waveforms. Further, since the pattern is simple, the pattern can be easily formed. This pattern is suitable for increasing the load capacitances C2a, C2b as much as possible, and reducing the footprint as small as possible.

### Third Embodiment

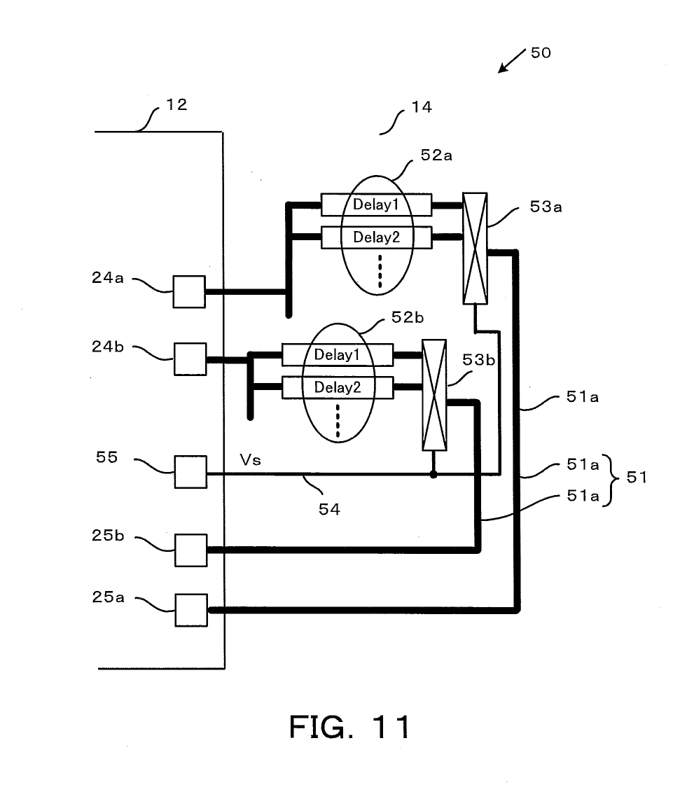

A semiconductor device of a third embodiment will be described with reference to FIG. 11. FIG. 11 is a top view showing a main portion of a semiconductor device. In the embodiment, the same constituent portions as those of the first embodiment are denoted with the same reference numerals, and the description thereabout will not be repeated. Only different portions will be described. The embodiment is different from the first embodiment in that a signal propagation delay of a signal wiring can be changed.

More specifically, as shown in FIG. 11, a wiring 51a of a signal wiring 51 in a semiconductor device 50 of the embodiment includes a delay line group 52a having a plurality of delay lines having respectively different delays in the wiring. One end of each of the plurality of delay lines is connected to a signal output pad 24a. The other end of each of the plurality of delay lines is connected to a signal input pad 25a via a selector 53a.

A wiring 51b is configured in the same manner as the wiring 51a. The wiring 51b includes a delay line group 52b having a plurality of delay lines having respectively different delays in the wiring. One end of each of the plurality of delay lines is connected to a signal output pad 24b. The other end of each of the plurality of delay lines is connected to a signal input pad 25b via a selector 53b.

The selectors 53a, 53b are connected to a selection signal pad 55 via a wiring 54. The delay line groups 52a, 52b and the selectors 53a, 53b are formed on the dicing line 14.

The delay line groups 52a, 52b are series circuit groups of inverters each having a different number of stages from each other, for example. Accordingly, the delay line groups 52a, 52b provide the delay lines having different delays in accordance with the number of stages of the inverter, as is well-known.

Each of the selectors 53a, 53b has a decoder and a switching circuit. The decoder decodes a selection signal Vs, and determines a delay line to be selected from among the delay line groups 52a, 52b. The switching circuit selects the determined delay line. The selection signal Vs is generated by an internal circuit 21 during the external loopback test, for example.

Therefore, the signal propagation delay of the signal wiring 51 can be changed. The delay line selected from the delay line group 52a and the delay line selected from the delay line group 52b may have the same or different delays. More specifically, a delay line Delay1 may be selected from the delay line group 52a, and the delay line Delay1 may be selected from the delay line group 52b. Alternatively, the delay line Delay1 may be selected from the delay line group 52a, and a delay line Delay2 may be selected from the delay line group 52b.

When delay lines having the same delay are selected, this allows performing a test to check whether operation can be normally performed or not even when there is a signal propagation delay within a range defined by a standard, for example. When delay lines having different delays are selected, this allows performing a test to check how much phase difference is tolerated between a data signal 33a and a clock signal 33b of a differential signal Vds as shown in FIG. 3 so as to normally perform operation.

As described above, in the embodiment, the signal propagation delay of the signal wiring 51 can be changed by the selection signal Vs. This pattern is suitable for checking a margin for timing of operation in the external loopback test.

### Fourth Embodiment

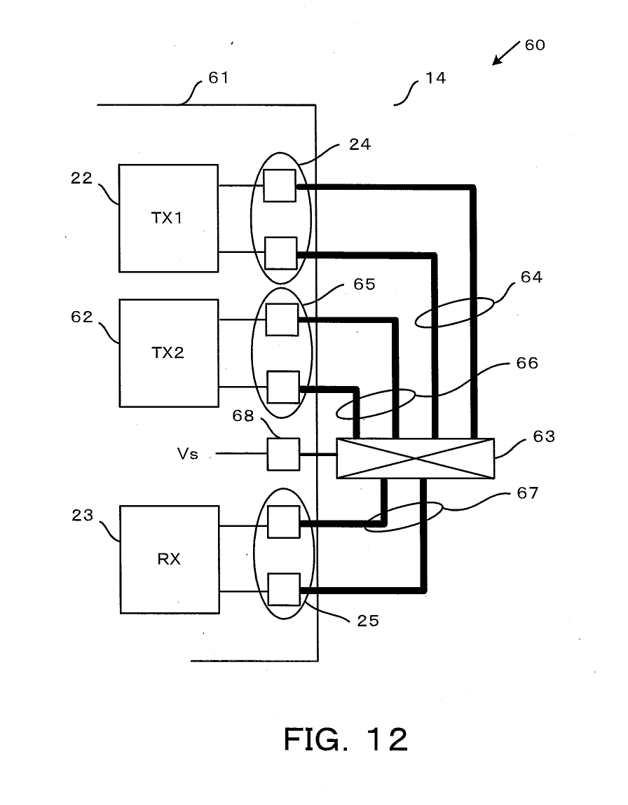

A semiconductor device of a fourth embodiment will be described with reference to FIG. 12. FIG. 12 is a top view showing a main portion of a semiconductor device. In the embodiment, the same constituent portions as those of the first embodiment are denoted with the same reference numerals, and the description thereabout will not be repeated. Only different portions will be described. The embodiment is different from the first embodiment in that an integrated circuit includes a plurality of transmitter circuits.

As shown in FIG. 12, a semiconductor device 60 of the embodiment is configured such that an integrated circuit 61 includes two transmitter circuits 22, 62, and a receiver circuit 23. The transmitter circuits 22, 62 may have the same characteristic or different characteristics.

A selector 63 is formed on a dicing line 14. The selector 63 is arranged to select whether an external loopback test is performed between the transmitter circuit 22 and the receiver circuit 23 or between the transmitter circuit 62 and the receiver circuit 23 in accordance with a selection signal Vs.

The transmitter circuit 22 has a signal output pad 24 connected to one of input terminals (not shown) of the selector 63 via the signal wiring 64. The transmitter circuit 62 has a signal output pad 65 connected to the other of the input terminals of the selector 63 via the signal wiring 66.

The receiver circuit 23 has a signal input pad 25 connected to an output terminal of the selector 63 via a signal wiring 67. A control terminal of the selector 63 is connected to a selection signal pad 68.

As described above, the semiconductor device 60 according to the embodiment includes the two transmitter circuits 22, 62 and the selector 63, and can perform both of the external loopback test between the transmitter circuit 22 and the receiver circuit 23 and the external loopback test between the transmitter circuit 62 and the receiver circuit 23.

In above description, the integrated circuit 61 includes the two transmitter circuits 22, 62 and the receiver circuit 23. However, the number of transmitter circuits is not particularly limited thereto. Even when the number of transmitter circuits increases, there is an advantage in that the external loopback test can be performed with a least number of signal wirings.

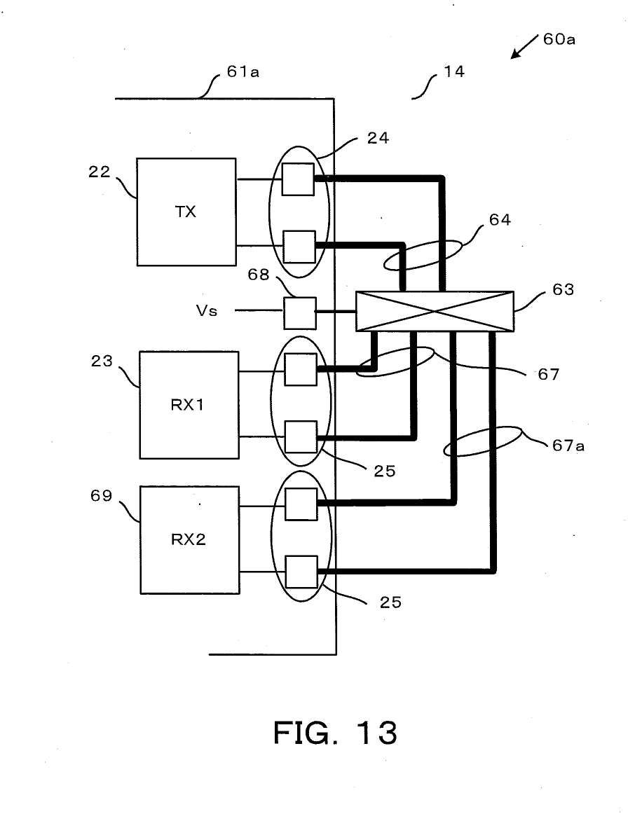

This embodiment can be carried out even when the integrated circuit includes one transmitter circuit and a plurality of receiver circuits or when the integrated circuit includes a plurality of transmitter circuits and a plurality of receiver circuits. FIG. 13 is a top view showing a main portion of a semiconductor device in a case where an integrated circuit includes one transmitter circuit and a plurality of receiver circuits. As shown in FIG. 13, a semiconductor device 60a is configured such that an integrated circuit 61a includes a transmitter circuit 22 and two receiver circuits 23, 69. The receiver circuits 23, 69 may have the same characteristic or different characteristics. A selector 63 selects whether an external loopback test is performed between the transmitter circuit 22 and the receiver circuit 23 or between the transmitter circuit 22 and the receiver circuit 69 in accordance with a selection signal Vs. The transmitter circuit 22 has a signal output pad 24 connected to an output terminal of the selector 63 via a signal wiring 64. The receiver circuit 23 has a signal input pad 25 connected to one of input terminals of the selector 63 via a signal wiring 67. The receiver circuit 69 has a signal input pad 25 connected to the other of input terminals of the selector 63 via a signal wiring 67a.

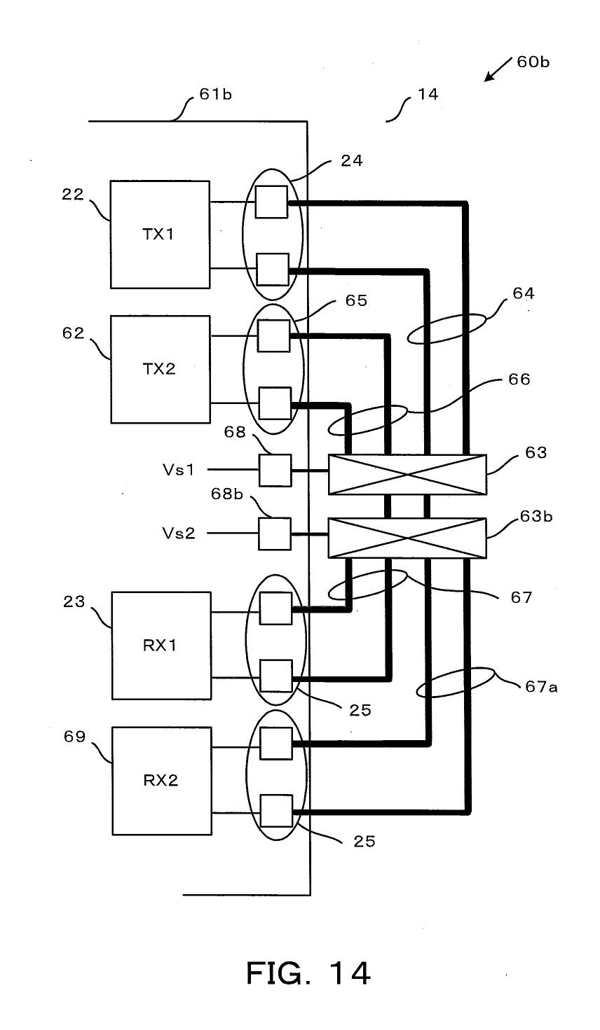

FIG. 14 is a top view showing a main portion of a semiconductor device in a case where the integrated circuit includes a plurality of transmitter circuits and a plurality of receiver circuits. As shown in FIG. 14, a semiconductor device 60b is configured such that an integrated circuit 61b includes two transmitter circuits 22, 62 and two receiver circuits 23, 69. A selector 63 selects the transmitter circuit 22 or the transmitter circuit 62 in accordance with a first selection signal Vs1. A selector 63b selects the receiver circuit 23 or the receiver circuit 69 in accordance with a second selection signal Vs2. An external loopback test is performed between the selected transmitter circuit and the selected receiver circuit.

### Fifth Embodiment

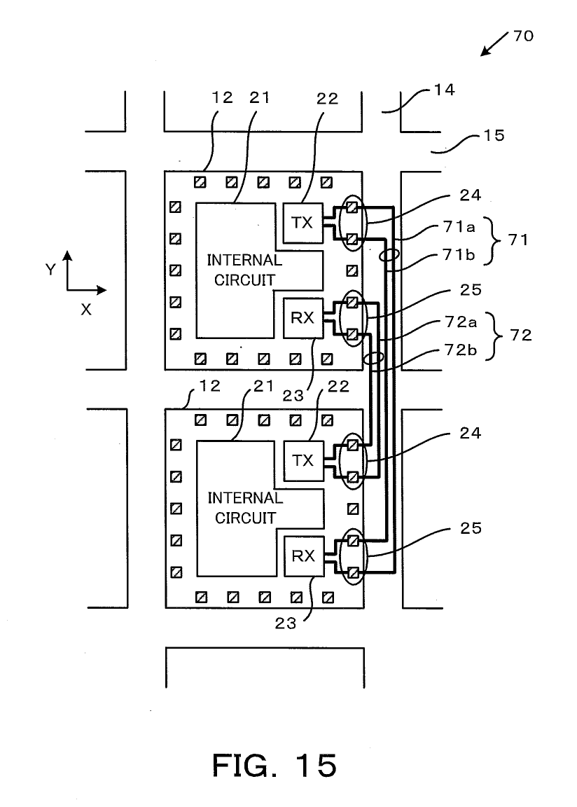

A semiconductor device of a fifth embodiment will be described with reference to FIG. 15. FIG. 15 is a top view showing a main portion of a semiconductor device. In the embodiment, the same constituent portions as those of the first embodiment are denoted with the same reference numerals, and the description thereabout will not be repeated. Only different portions will be described. The embodiment is different from the first embodiment in that an external loopback test is performed with another integrated circuit.

As shown in FIG. 15, a semiconductor device 70 of the embodiment includes first and second integrated circuits 12 arranged adjacent to each other in a Y direction, wherein a signal output pad 24 of a transmitter circuit 22 of the first integrated circuit 12 is connected, via a first signal wiring 71, to a signal input pad 25 of a receiver circuit 23 of the second integrated circuit 12. Likewise, a signal output pad 24 of a transmitter circuit 22 of the second integrated circuit 12 is connected, via a second signal wiring 72, to a signal input pad 25 of a receiver circuit 23 of the first integrated circuit 12.

The first and second signal wirings 71, 72 intersecting a dicing line 15 arranged along one side of the first and second integrated circuits 12 in parallel with the Y direction. The first and second signal wirings 71, 72 are formed on the dicing line 14.

Therefore, the transmitter circuit 22 of the first integrated circuit 12 can transmit data to the receiver circuit 23 of the second integrated circuit 12. The transmitter circuit 22 of the second integrated circuit 12 can reply the received data to the receiver circuit 23 of the first integrated circuit 12. Therefore, the external loopback test can be performed.

At this moment, it is to be understood that the transmission path length of the wiring 71a of the first signal wiring 71 is the same as the transmission path length of the wiring 71b of the first signal wiring 71, and the transmission path length of the wiring 72a of the first signal wiring 72 is the same as the transmission path length of the wiring 72b of the first signal wiring 72.

As described above, in the embodiment, the first and second integrated circuits 12 are arranged adjacent to each other, and the transmitter circuit 22 and the receiver circuit 23 of them both are connected via the first and second signal wirings 71, 72. As a result, the external loopback test is performed between the first and second integrated circuits 12.

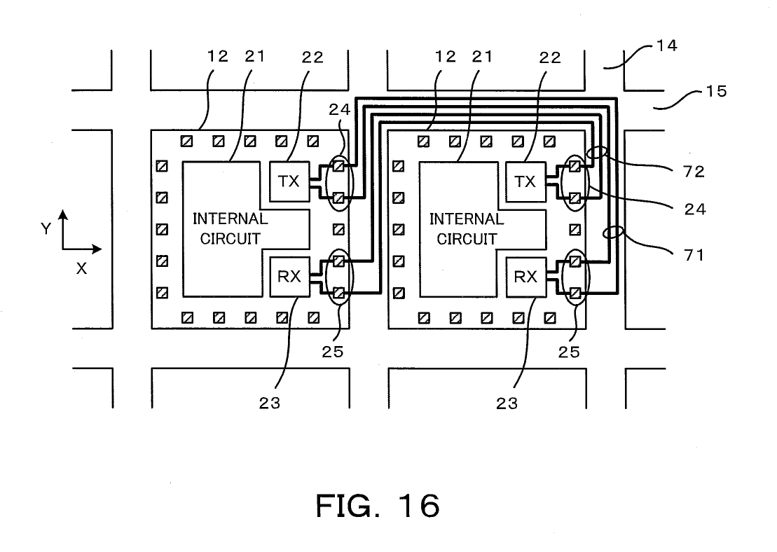

In the above description, the first and second integrated circuits 12 are arranged adjacent to each other in the Y direction. Alternatively, the first and second integrated circuits 12 may be arranged adjacent to each other in the X direction. FIG. 16 is a figure showing an external loopback test where the first and second integrated circuits 12 are arranged adjacent to each other in the X direction. It should be noted that the external loopback test can be performed even when the two integrated circuits 12 are not arranged adjacent to each other.

An external loopback test may be performed with any integrated circuit other than the integrated circuit 12. The external loopback test may be performed between an integrated circuit having only a receiver circuit and an integrated circuit having only a transmitter circuit or between integrated circuits where a transmitter circuit and a receiver circuit are arranged away from each other, for example.

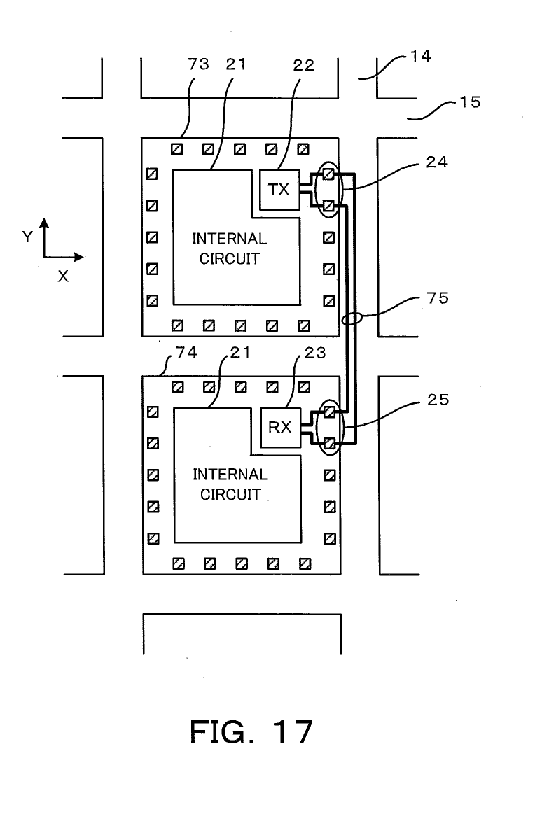

FIG. 17 shows an external loopback test between an integrated circuit having only a transmitter circuit and an integrated circuit having only a receiver circuit. As shown in FIG. 17, two integrated circuits 73, 74 are arranged adjacent to each other in the Y direction, wherein the integrated circuit 73 has only a transmitter circuit 22, and wherein the integrated circuit 74 has only a receiver circuit 23.

A signal output pad 24 of the transmitter circuit 22 of the integrated circuit 73 is electrically connected, via a signal wiring 75, to a signal input pad 25 of the receiver circuit 23 of the integrated circuit 74. An external loopback test may be performed as follows, for example.

The transmitter circuit 22 of the integrated circuit 73 transmits data to the receiver circuit 23 of the integrated circuit 74. The receiver circuit 23 of the integrated circuit 74 receives the transmitted data, and gives the data to an internal circuit 21 of the integrated circuit 74. The internal circuit 21 of the integrated circuit 74 gives the received data to an internal circuit 21 of the integrated circuit 73 by way of an external circuit, e.g., an external tester. The internal circuit 21 of the integrated circuit 73 collates the transmitted data with the received data.

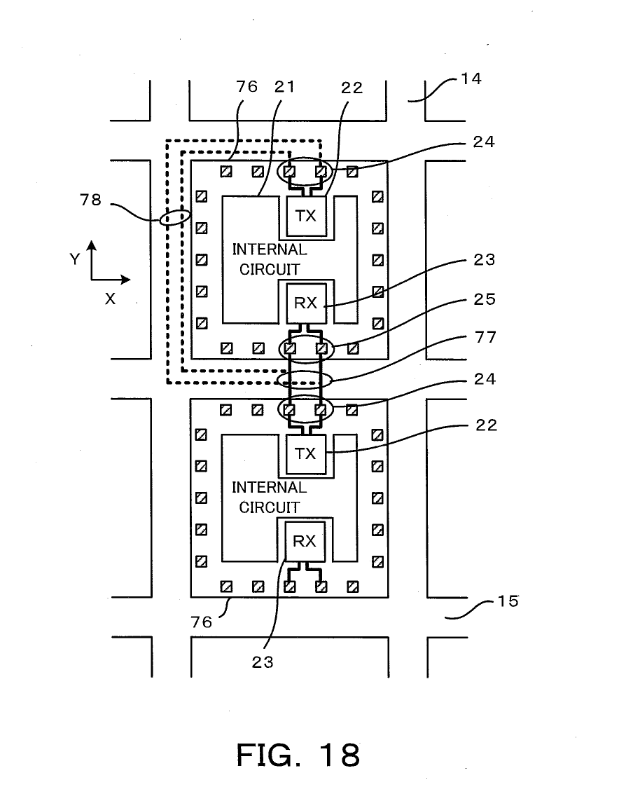

FIG. 18 shows an external loopback test between integrated circuits where a transmitter circuit and a receiver circuit are arranged away from each other. As shown in FIG. 18, first and second integrated circuits 76 are arranged adjacent to each other in the Y direction, wherein a transmitter circuit 22 is arranged on one side of the integrated circuit 76 in parallel with an X direction, and wherein a receiver circuit 23 is arranged on the other side facing the one side of the integrated circuit 76. In other words, the transmitter circuit 22 of the first integrated circuit 76 and the receiver circuit 23 of the second integrated circuit 76 face each other via a dicing line 15.

A signal output pad 24 of the transmitter circuit 22 of the first integrated circuit 76 can be electrically connected, via a short signal wiring 77, to a signal input pad 25 of the transmitter circuit 23 of the second integrated circuit 76.

When an external loopback test is performed with only the second integrated circuit 76, it is necessary to electrically connect, via a long wiring 78, between the signal output pad 24 of the transmitter circuit 22 of the first integrated circuit 76 and the signal output pad 25 of the transmitter circuit 23 of the second integrated circuit 76.

### Sixth Embodiment

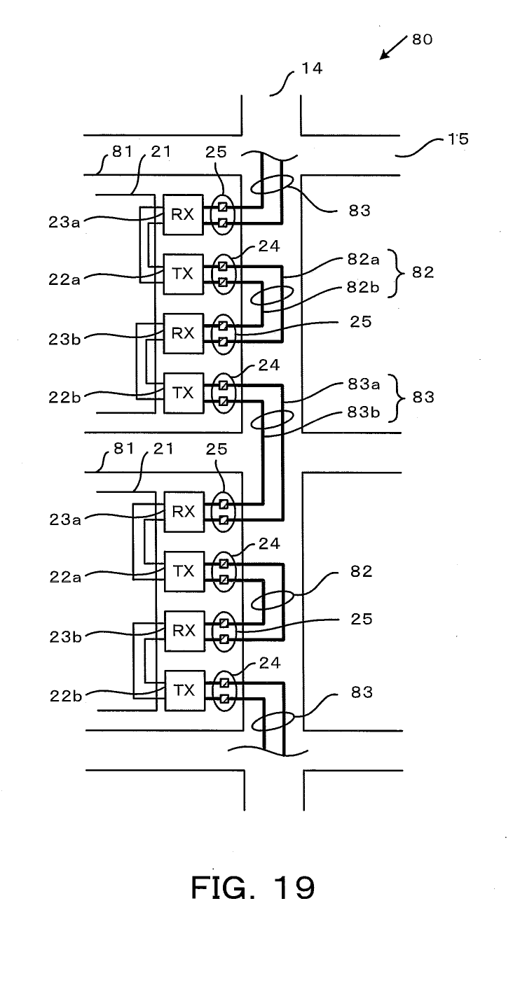

A semiconductor device of a sixth embodiment will be described with reference to FIG. 19. FIG. 19 is a top view showing a main portion of a semiconductor device. In the embodiment, the same constituent portions as those of the first embodiment are denoted with the same reference numerals, and the description thereabout will not be repeated. Only different portions will be described. The embodiment is different from the first embodiment in that an external loopback test can be performed through a plurality of transmitter circuit s and a plurality of receiver circuits.

As shown in FIG. 19, in a semiconductor device 80 of the embodiment, each of integrated circuits 81 includes two transmitter circuits 22a, 22b and two receiver circuits 23a, 23b. The transmitter circuits 22a, 22b and the receiver circuits 23a, 23b are arranged alternately on one side in parallel with a Y direction.

In the integrated circuit 81, a signal output pad 24 of a transmitter circuit 22a and a signal input pad 25 of an adjacent receiver circuit 23b are electrically connected via a first signal wiring 82. The internal circuit 21 has an internal through-test function for transmitting data received by the receiver circuit to the transmitter circuit without processing the data. The receiver circuit 23a and the transmitter circuit 22a are substantially connected by the internal through-test function. The receiver circuit 23b and the transmitter circuit 22b are substantially connected by the internal through-test function.

The signal output pad 24 of the transmitter circuit 22b of the first integrated circuit 81 is electrically connected, via a second signal wiring 83, to the signal input pad 25 of the receiver circuit 23a of the second integrated circuit 81 adjacent to the first integrated circuit 81 in the Y direction.

In the integrated circuits 81, the plurality of transmitter circuits and the plurality of receiver circuits are alternately connected in series by the first signal wiring 82 and the internal through-test function. The first and second integrated circuits 81 arranged adjacent to each other in the Y direction are connected in series via the second signal wiring 83.

The first signal wiring 82 is formed on a dicing line 14. The second signal wiring 83 intersects a dicing line 15, and is formed on the dicing line 14.

An external loopback test may be performed as follows, for example. First, an external circuit, e.g., a tester connected to the first integrated circuit 81, inputs data to the receiver circuit 23a of the first integrated circuit 81.

When the receiver circuit 23a receives data, the receiver circuit 23a gives data to the internal circuit 21. The internal circuit 21 uses the internal through-test function to transmit the received data to the transmitter circuit 22a without processing the received data. The transmitter circuit 22a transmits the received data to the receiver circuit 23b via the first signal wiring 82.

When the receiver circuit 23b receives the data, the receiver circuit 23b gives the data to the internal circuit 21. The internal circuit 21 uses the internal through-test function to transmit the received data to the transmitter circuit 22b without processing the received data. The transmitter circuit 22b transmits the received data to the receiver circuit 23a of the adjacent second integrated circuit 81 via the signal wiring 83.

This data transmission is repeated until the data reaches the end of the second integrated circuit 81. The transmitter circuit 22b at the end of the second integrated circuit 81 replies the data to the external circuit without processing the data. As described above, the external loopback test can be performed through the plurality of transmitter circuits and the plurality of receiver circuits.

At this moment, it is to be understood that the transmission path length of the wire 82a of the first signal wire 82 is the same as the transmission path length of the wire 82b of the first signal wire 82, and the transmission path length of the wire 83a of the first signal wire 83 is the same as the transmission path length of the wire 83b of the first signal wire 83.

As described above, the semiconductor device 80 of the embodiment includes the transmitter circuits 22 and the receiver circuits 23 of the first and second integrated circuits 81, which are substantially connected in series. As a result, the external loopback test for the first and second integrated circuits 81 can be performed at a time. Therefore, there is an advantage in that the test can be finished in a shorter time.

In the above description, the integrated circuit 81 includes the two transmitter circuits and the two receiver circuits. However, the number of transmitter circuits and the number of receiver circuits are not limited thereto. Further, the number of transmitter circuits may not be the same as the number of receiver circuits. Still further, the number of integrated circuits subjected to the external loopback test at a time is not particularly limited either.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
an integrated circuit formed in an area enclosed by a plurality of dicing lines formed in a matrix manner, the integrated circuit including a transmitter circuit having a signal output pad, a receiver circuit having a signal input pad and an internal circuit to process data inputted to the transmitter circuit and outputted from the receiver circuit; and
a signal wiring formed on at least one of the dicing lines, the signal wiring electrically connecting the signal output pad and the signal input pad.

2. The semiconductor device according to claim 1, wherein the signal wiring includes:
a plurality of delay lines formed on at least one of the dicing lines, and having mutually different delays; and
a selector formed on at least one of the dicing lines, and to select any one of the plurality of delay lines in accordance with a selection signal.

3. The semiconductor device according to claim 1, wherein the integrated circuit includes a plurality of the transmitter circuit, a selector is formed on at least one of the dicing lines, the selector selecting any one of the transmitter circuits in accordance with a selection signal, and electrically connecting the selected transmitter circuit and the receiver circuit.

4. The semiconductor device according to claim 1, wherein the integrated circuit includes a plurality of the receiver circuit, a selector is formed on at least one of the dicing lines, the selector selecting any one of the receiver circuits in accordance with a selection signal, and electrically connecting the transmitter circuit and the selected receiver circuit.

5. The semiconductor device according to claim 1, wherein the integrated circuit includes a plurality of the transmitter circuit and a plurality of the receiver circuit, a first selector is formed on at least one of the dicing lines, the first selector selecting any one of the transmitter circuits in accordance with a first selection signal, and a second selector is formed on at least one of the dicing lines, the second selector selecting any one of the receiver circuits in accordance with a second selection signal.

6. The semiconductor device according to claim 1, wherein the signal input pad includes a pair of pads, the signal output pad includes a pair of pads, and the signal wiring includes a pair of wirings.

7. The semiconductor device according to claim 6, wherein the pair of wirings have a first wiring near side to the integrated circuit and a second wiring far side from the integrated circuit, transmission path length of the first wiring is the same as transmission path length of the second wiring.

8. The semiconductor device according to claim 6, wherein the first wiring has a non-straight line pattern, and the second wiring has a straight line pattern.

9. The semiconductor device according to claim 6, wherein the first and the second wirings have a rectangular waveform pattern respectively.

10. The semiconductor device according to claim 9, wherein the duty of the rectangular wave of the first wiring and the duty of the rectangular wave of the second wiring are different, the summation of the duty of the rectangular wave of the first wiring and the duty of the rectangular wave of the second wiring is substantially 1.

11. The semiconductor device according to claim 6, wherein the first and the second wirings have a planar-shaped pattern respectively.

12. The semiconductor device according to claim 11, wherein the area of the first wiring having the planar-shaped pattern is the same as the area of the second wiring having the planar-shaped pattern.

13. The semiconductor device according to claim 1, wherein the leading portion of the signal wiring intersecting one of the dicing lines is formed to extend beyond the center line of one of the dicing lines.

14. The semiconductor device according to claim 1, wherein the signal wiring is made of aluminum or an alloy mainly including aluminum.

15. A semiconductor device, comprising:
first and second integrated circuits respectively formed in an area enclosed by a plurality of dicing lines formed in a matrix manner, the first and second integrated circuits respectively including a transmitter circuit having a signal output pad, a receiver circuit having a signal input pad and an internal circuit to process data inputted to the transmitter circuit and outputted from the receiver circuit;
a first signal wiring formed on at least one of the dicing lines, the first signal wiring electrically connecting the signal output pad of the first integrated circuit and the signal input pad of the second integrated circuit; and
a second signal wiring formed on at least one of the dicing lines, the second signal wiring electrically connecting the signal input pad of the first integrated circuit and the signal output pad of the second integrated circuit.

16. The semiconductor device according to claim 15, wherein the signal input pad includes a pair of pads, the signal output pad includes a pair of pads, and the first and the second signal wirings include a pair of wirings respectively.

17. The semiconductor device according to claim 16, wherein the pair of wirings have a first wiring near side to the first and second integrated circuits and a second wiring far side from the first and second integrated circuits, transmission path length of the first wiring is the same as transmission path length of the second wiring.

18. A semiconductor device, comprising:
first and second integrated circuits respectively formed in an area enclosed by a plurality of dicing lines formed in a matrix manner, the first and second integrated circuits respectively including a plurality of transmitter circuits having a signal output pad, a plurality of receiver circuits having a signal input pad, and an internal circuit to process data inputted to the plurality of transmitter circuits and outputted from the plurality of receiver circuits; and
first and second signal wirings respectively formed on at least one of the dicing lines, the first and second signal wirings electrically connecting the signal output pad and the signal input pad,
wherein the plurality of transmitter circuits and the plurality of receiver circuits are alternately connected in series via the first signal wiring and the through-test function of the internal circuit in effect, and
wherein the transmitter circuit of the first integrated circuit and the receiver circuit of the second integrated circuit are electrically connected via the second signal wiring.

19. The semiconductor device according to claim 18, wherein the signal input pad includes a pair of pads, the signal output pad includes a pair of pads, and the first and the second signal wirings include a pair of wirings respectively.

20. The semiconductor device according to claim 18, wherein the pair of wirings have a first wiring near side to the first or second integrated circuits and a second wiring far side from the first or second integrated circuits, transmission path length of the first wiring is the same as transmission path length of the second wiring.
